(19) United States
(12) Patent Application Publication
(10) Pub. No.: US 2026/0025908 A1
(43) Pub. Date: Jan. 22, 2026

(54) PRINTED CIRCUIT BOARD ARRANGEMENT FOR AN ELECTRONICS UNIT, METHOD OF PRODUCING THE PCB ARRANGEMENT AND ELECTRONICS UNIT

(71) Applicant: Brose Fahrzeugteile SE & Co. Kommanditgesellschaft, Würzburg, Würzburg (DE)

(72) Inventors: Maik RÜMMLER, Breitengüssbach (DE); Vijaykumar JADHAV, Bamberg (DE)

(21) Appl. No.: 19/270,543

(22) Filed: Jul. 16, 2025

(30) Foreign Application Priority Data
Jul. 22, 2024 (DE) 10 2024 206 865.9

(51) Int. Cl. H05K 1/02; H02K 11/33; H05K 1/18; H05K 3/30

(52) U.S. Cl. CPC H05K 1/0204; H02K 11/33; H05K 1/181; H05K 3/303; H02K 2211/03

(57) ABSTRACT

A printed circuit board configuration for an electronics unit contains a printed circuit board with a first printed circuit board side on which at least one solder point for contacting an electronic component is arranged, and with an oppositely situated printed circuit board side on which a thermal surface is arranged. The thermal surface is arranged so as to be vertically aligned with the solder point. The at least one via connecting the solder point and the thermal surface is introduced into the printed circuit board. The or each via is enclosed by a circumferentially continuous solder mask acting as a flow barrier.

### CROSS-REFERENCE TO RELATED APPLICATION

This application claims the priority, under 35 U.S.C. § 119, of German Patent Application DE 10 2024 206 865.9, filed Jul. 22, 2024; the prior application is herewith incorporated by reference in its entirety.

### FIELD AND BACKGROUND OF THE INVENTION

The invention relates to a printed circuit board arrangement for an electronics unit, containing a printed circuit board with a first printed circuit board side, on which at least one solder point for contacting an electronic component is arranged, and with an oppositely situated printed circuit board side, on which a thermal surface is arranged. The invention further relates to a method for manufacturing a printed circuit board arrangement and to an electronics unit for an electric motor.

In a modern motor vehicle, electric motors are used in a variety of ways as drives for different actuators. Electric motors are used, for example, as window lifter drives, sunroof or seat adjustment drives, as steering drives (EPS, Electrical Power Steering), as radiator fan drives, or as gear actuators. Such electric motors must have a relatively high torque or power density and be operationally reliable even at high temperatures.

A brushless electric motor, particularly in the form of an electric (three-phase) machine, usually contains a stator that is provided with a field or stator winding, which is arranged coaxially with a rotor with one or more permanent magnets. Both the rotor and the stator are, for example, constructed as laminated cores, with stator teeth in intervening stator slots carrying the coils of the field winding.

In a brushless electric motor, the alternating current used to supply the stator winding is usually generated by a converter (power inverter, inverter). In smaller electric motors, this converter, together with the associated control electronics, is often housed in an electronics compartment (electronics space) that is integrated into the motor housing.

The (control) electronics usually comprise a printed circuit board on which (power) semiconductor switches are arranged as electronic components of the converter. When high power is required, the electric currents and voltages switched by means of the semiconductor switches are comparatively large, resulting in comparatively high losses. The losses consist of switching losses of the semiconductor switches, dead-time losses, and direct current losses. Therefore, relatively pronounced heating of the semiconductor switches can occur during motor operation.

The heat dissipation or cooling of the electronics occurs, for example, via a heat sink and its surrounding components to a thermal sink. In this case, for example, a housing surface of the electronics compartment is used as a heat sink and is connected in a thermally conductive manner to the printed circuit board and/or semiconductor switch via a thermally conductive medium—for example, via a gap filler, a thermal pad, or a thermal paste.

The electronic components can be mounted on the printed circuit board as surface-mounted devices (SMDs) by means of surface-mounting technology (SMT). The components are soldered directly onto the solder points of the printed circuit board using solderable connection surfaces or pins (flat arrangement).

To cool such electronic components, it is possible to use a thermal surface that is situated opposite the solder point, for example a copper pad, and to couple the component directly to the thermal surface using feedthroughs (Vertical Interconnect Accesses, or vias) to ensure good heat transfer to the heat sink and/or to the environment. The most efficient method to produce these “thermal” vias is through direct implementation beneath the component housing, directly in the solder point.

If the component has a large solder point underneath, the solder material might flow through this via, thus causing a short circuit to the heat sink on the opposite side of the printed circuit board. To avoid this problem, filled and capped/covered vias are generally used, making the manufacturing of the printed circuit board more complex and cost-intensive.

### SUMMARY OF THE INVENTION

It is the object of the invention to provide an especially suitable printed circuit board arrangement for an electronics unit. In particular, simple and reliable thermal coupling between an electronic component and a heat sink and/or the environment is to be made possible. It is also the object of the invention to provide an especially suitable method for manufacturing such a printed circuit board arrangement and an especially suitable electronics unit for an electric motor.

With regard to the printed circuit board arrangement, the object is achieved according to the invention with the features of the independent printed circuit board arrangement claim; with regard to the method, the object is achieved with the features of the independent method claim; and with regard to the electronics unit, the object is achieved with the features of the independent electronics unit claim. Advantageous embodiments and refinements are the subject of the dependent claims (subclaims).

The advantages and embodiments mentioned with regard to the printed circuit board arrangement can also be applied to the electronics unit and/or to the method and vice versa. The conjunction “and/or” is to be understood here and in the following such that the features linked by this conjunction can be formed both jointly and as alternatives to one another.

The printed circuit board arrangement according to the invention is intended for an electronics unit, in particular for control electronics for an electric motor, and is suitable and configured for the same. The printed circuit board arrangement comprises a printed circuit board (PCB) with a first printed circuit board side and an oppositely situated printed circuit board side. The printed circuit board sides arranged so as to be parallel to each other form the flat surfaces (top side, bottom side) or outer layers of the printed circuit board on which electronic components of the electronics unit can be arranged.

A “printed circuit board” is understood here and below to mean in particular a plate or board which provides electrical connections and mechanical fastenings for electronic components. The printed circuit board comprises, for example, an insulating substrate material that is provided with conductive connections made of copper.

On the oppositely situated side of the printed circuit board, a thermal surface or thermal pad is provided for thermally conductive coupling to a heat sink of the electronics unit and/or to the environment. The electronic component is, for example, an SMD component which does not require through-hole mounting and which, in the contacted state, is soldered to the solder point by means of a solderable connection surface.

On the oppositely situated side of the printed circuit board, a thermal surface or thermal pad is provided for thermally conductive coupling to a heat sink of the electronics unit and/or to the environment. The thermal surface is made, for example, of a metal, in particular copper. A thermal interface material—i.e., a material that is thermally conductive but electrically insulating—is provided for thermal coupling, for example. The thermal interface material is, for example, a gap filler or a thermally conductive material (e.g., made of filled silicone).

Relative to a vertical direction oriented perpendicular to the sides of the printed circuit board, the thermal surface is arranged so as to be vertically aligned with the solder point. The thermal surface, the printed circuit board, and the solder point are thus arranged in a substantially vertical stack. At least one via connecting the solder point and the thermal surface is introduced into the printed circuit board. The via penetrates completely through the printed circuit board; in other words, the via extends over the entire (vertical) thickness of the printed circuit board from one side of the printed circuit board to the other side of the printed circuit board.

A “feedthrough” or “(through) via” is understood here and below to mean in particular a through hole in the printed circuit board into which conductive material, in particular thermally conductive material, for example in the form of a hollow cylindrical or tubular sleeve, is introduced, enabling a thermal and/or electrical connection between the sides of the printed circuit board.

According to the invention, the or each via is enclosed by a circumferentially continuous solder mask. In other words, a solder mask ring is provided around the opening of the via. A “solder mask” or “solder resist mask” is understood here and below to mean in particular a protective layer that is applied to one side of a printed circuit board in order to keep certain areas free of solder (tin solder) and to prevent short circuits.

The solder mask on the printed circuit board surface thus acts as a flow barrier against molten tin solder during the soldering connection/contacting of the electronic component with the solder point. This prevents molten solder from flowing through the via and causing a short circuit with a heat sink. As a result, cost-intensive filled and capped/covered vias can be dispensed with, whereby an especially simple and cost-effective printed circuit board arrangement is realized.

Preferably, a plurality of vias, i.e. at least two vias, in particular more than 16 vias, are introduced between the solder point and the thermal surface.

In a preferred embodiment, the or each via is open on both sides. This means that the openings to the sides of the printed circuit board are not tented, plugged, or filled.

In order to achieve especially effective heat transfer or especially effective thermal coupling between the electronic component mountable on the printed circuit board and a heat sink or an environment, a provision is made in one expedient embodiment that the or each via is arranged completely within the solder point and the thermal surface. The via is therefore integrated directly into the solder point and the thermal surface. In an equally expedient refinement, the via is connected to the thermal surface, creating a direct connection between the conductive material of the via and the thermal surface.

In a preferred embodiment, the or each solder mask is arranged on the first printed circuit board side. This means that the solder mask is positioned on the side of the solder point. The solder mask ring on the printed circuit board surface thus acts as a dam on the soldering side, preventing the solder from flowing through or into the via. This prevents solder wicking (or solder drainage) in the via.

The method according to the invention is intended for the manufacture of a printed circuit board arrangement described above and is suitable and designed for that purpose. According to the method, a printed circuit board is provided with a first printed circuit board side on which at least one solder point for contacting an electronic component is arranged and with an oppositely situated printed circuit board side on which a thermal surface is arranged so as to be vertically aligned with the solder point. At least one via connecting the solder point and the thermal surface is introduced into the printed circuit board. Finally, a circumferentially continuous solder mask which encloses the respective via is produced around the or each via as a flow barrier. This provides an especially suitable method for manufacturing the printed circuit board arrangement.

The solder mask rings are produced in particular during printed circuit board manufacturing. The surface of the printed circuit board is usually coated with solder mask (curtain coating or spraying). Areas in which the solder resist is to remain (e.g., the solder mask rings) are exposed/crosslinked accordingly by means of masking. In a later chemical process, all non-crosslinked areas are removed, such as the areas located inside and outside the solder mask rings.

In an advantageous embodiment, the or each solder mask is produced using a screen printing method. The term “screen printing” or “screen printing process” is understood here and below to mean, in particular, a printing process in which materials are applied to the surface of the printed circuit board using a fine-mesh screen. In screen printing, a stencil which defines the areas to be printed is placed on the screen. Pressure forces the ink through the open mesh of the screen onto the side of the printed circuit board.

For example, the solder mask material is applied directly to the printed circuit board surface using screen printing. Preferably, the printed circuit board surface is already provided with a solder mask layer, and a photoresist is applied to the solder mask layer using screen printing. The photoresist is exposed and developed photolithographically, and then all areas of the solder mask layer not covered with photoresist are removed (etched), leaving only the solder mask rings. Finally, the remaining photoresist is removed.

Preferably, the screen printing process employs a stencil which has a circumferentially continuous depression or cavity (cavities) in the vicinity of the or each solder mask. These depressions in the stencil enable the stencil to sit snugly and flat against the surface of the printed circuit board without the solder mask or photoresist lifting or interfering with the stencil.

The inventive electronics unit is intended for an electric motor and is suitable and configured for the same. The electric motor is, for example, part of an electric motor fan drive, in which case the electronics unit preferably has an electronics compartment integrated into a motor housing and a cover closing this compartment.

The electronics unit further comprises a printed circuit board arrangement as described above. The printed circuit board arrangement is equipped with electronic components which form a converter or inverter circuit, for example. An electronic component is electrically soldered or contacted to the solder point.

The electronic component is, for example, a power semiconductor switch, in particular a power transistor, or a controller, in particular a microcontroller. The electronic component is preferably embodied as an SMD component.

The solder mask in the vicinity of the via ensures that the risk of an electrical short circuit in the vicinity of the thermal surface is advantageously and simply avoided during soldering of the electronic component and solder point.

In a preferred embodiment, the thermal surface is connected in a thermally conductive manner to a heat sink, for example a radiator of the electronics unit. The thermal coupling can be achieved, for example, using a thermal paste.

Other features which are considered as characteristic for the invention are set forth in the appended claims.

Although the invention is illustrated and described herein as embodied in a printed circuit board arrangement for an electronics unit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective, exploded view of an electromotive radiator fan with an electronics unit according to the invention′

FIG. 2 is a diagrammatic side view of a printed circuit board arrangement of the electronics unit containing the printed circuit board with a solder point and with a thermal surface and with at least one via connecting them;

FIG. 3 is a top view of the printed circuit board arrangement with an electronic component;

FIG. 4 is a top view of the printed circuit board arrangement without an electronic component;

FIG. 5 is a top view of the printed circuit board arrangement according to FIG. 4 with solder applied;

FIG. 6 is a top view of a second embodiment of the printed circuit board arrangement;

FIG. 7 is a top view of a third embodiment of the printed circuit board arrangement;

FIG. 8 is a top view of representations of the printed circuit board arrangement and a stencil;

FIG. 9A is a top view of a printed circuit board side of the stencil, and

FIG. 9B is a top view of a squeegee side of the stencil.

### DETAILED DESCRIPTION OF THE INVENTION

Analogous parts are provided with the same reference symbols in all figures.

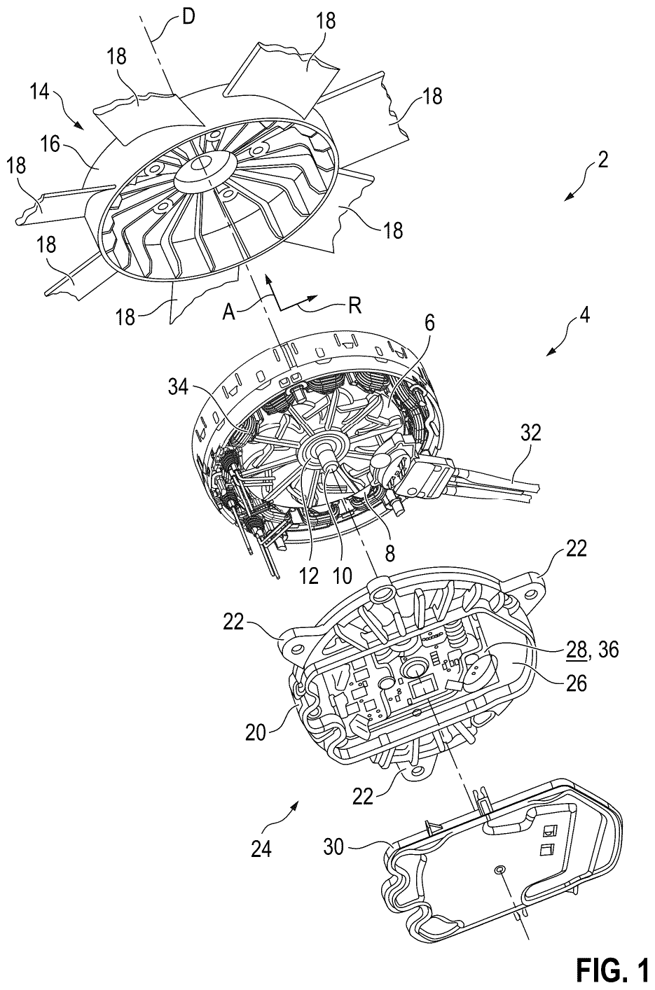

Referring now to the figures of the drawings in detail and first, particularly to FIG. 1 thereof, there is shown an exploded view of a radiator fan 2 for use in a motor vehicle (not shown in greater detail). The radiator fan 2 has an electric motor 4 with a rotor 6 and a stator 8 and is embodied, for example, as an internal rotor. However, in a variant of the electric motor 4 (not shown in greater detail), the rotor 6 is embodied as an external rotor. The following explanations apply analogously.

Here and in the following, “axial” or “axial direction A” is understood to mean in particular a direction parallel to (coaxial with) an axis of rotation D of the electric motor 4, i.e., perpendicular to the front sides of the stator 8. Accordingly, here and in the following, “radial” or a “radial direction” is understood to mean in particular a direction oriented perpendicular (transverse) to the axis of rotation of the electric motor along a radius of the electric motor. Here and in the following, “tangential” or a “tangential direction (T)” is understood to mean in particular a direction along the circumference of the stator (8) or the electric motor (circumferential direction, azimuthal direction), i.e., a direction perpendicular to the axial direction (A) and to the radial direction (R).

The rotor 6 is mounted so as to rotate about the rotation axis D by means of an axle pin 10, the rotation axis D running parallel to the axial direction A of the electric motor 2. The rotor 6 is supported by means of bearings 10, which are arranged at each end of the axle pin 10.

The rotor 6 is coupled on the front side to a fan wheel 14 for drive purposes. The radiator fan (2) is preferably embodied as an axial fan. The direction of conveyance—i.e., the direction of the air or volume flow generated by the rotation of the fan wheel 14—is thus oriented substantially parallel to the axial direction A.

The fan wheel 14 has a hub in a hub pot 16 and a number of blades (air guide vanes) 18 connected thereto, only portions of the blades 18 being shown in detail. The hub pot 16 represents the connection to the electric motor 4 or rotor 6, so that a torque generated by the latter during operation is transmitted to the fan wheel 14. The blades 18 are intended and/or configured to generate an air volume flow as soon as the fan wheel 14 is set in a rotary motion.

The hub pot 16 is a central part of the fan wheel 14 which, like a classic pot, is composed of a base surface and an adjoining cylindrical surface. The blades 18 are arranged, in particular formed, on this cylindrical outer wall. The hub pot 16 is arranged in the center of the fan wheel and at least partially covers the electric motor 4, in particular the stator 8.

A motor mount 20 with flanges 22 for fastening the radiator fan 2 is arranged on the front side of the electric motor 4 opposite the fan wheel 14. The motor mount 20 has, on its side facing away from the fan wheel 14, an electronics unit 24 with an electronics compartment 26 for (motor or control) electronics 28 of the electric motor 4, which is covered by an (electronics compartment) cover 30 when in the assembled state. The electronics 28 can be connected to a vehicle electrical system by means of a cable 32.

The electronics 28 has, for example, a converter circuit (not shown in greater detail) which converts a direct current transmitted via the cable 32 into a multi-phase alternating current (three-phase current) for energizing a rotating-field winding 34 carried by the stator 8.

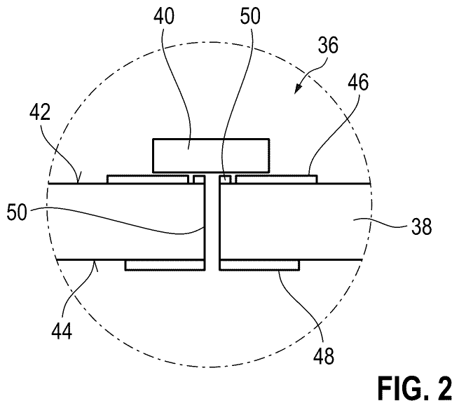

The electronics 28 has a printed circuit board arrangement 36, which will be explained in greater detail below with reference to FIGS. 2 to 7. The printed circuit board arrangement 36 has a printed circuit board 38 which, as a circuit carrier, carries the electronic components 40 of the electronics 28 or inverter circuit.

The printed circuit board 38 has two parallel printed circuit board sides 42, 44 which form the planar surfaces (top side, bottom side) or outer layers of the printed circuit board 38. The printed circuit board side 42, for example, faces toward the cover 30, while the printed circuit board side 44 faces toward a bottom of the electronics compartment 26.

A solder point 46 for electrical contact with the component 40 is provided on the printed circuit board side 42. The component 40 is, for example, an SMD component, in particular a power semiconductor switch or a (micro) controller.

A thermal surface 48 is arranged on the printed circuit board side 44 opposite the solder point 42. The thermal surface 48 is connected in a thermally conductive manner to a heat sink. In particular, the thermal surface 48 is connected in a thermally conductive manner to the bottom of the electronics compartment 26. The heat sink is in particular the electronics compartment 26 or the motor mount 20, which is coupled to a heat sink via the flanges 22.

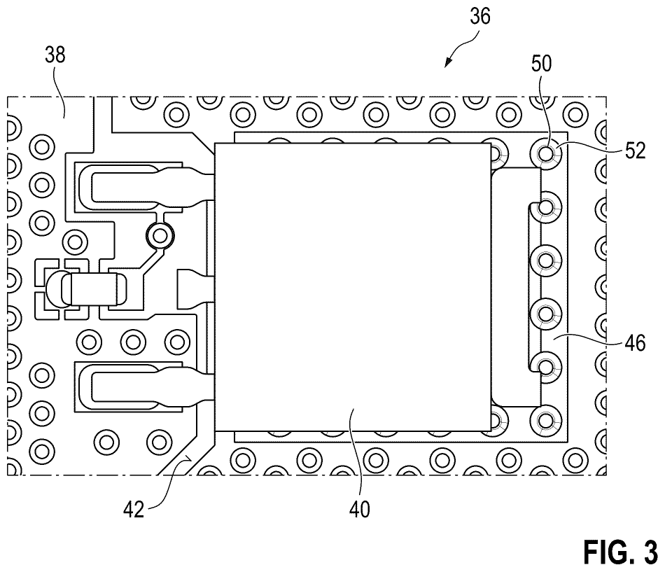

Relative to a vertical direction oriented perpendicular to the printed circuit board sides 42, 44, the thermal surface 48 is arranged so as to be vertically aligned with the solder point 46. In the assembled state, the vertical direction is oriented so as to be substantially parallel to the axial direction A. At least one via 50 connecting the solder point 46 and the thermal surface 48 is introduced axially or vertically into the printed circuit board 38. In each of the illustrations of FIGS. 3 to 7, a plurality of vias 50 are shown which are provided with reference numerals merely for the sake of example.

On the solder point side, i.e., on the printed circuit board side 42, the opening of the via 50 is surrounded by a (circular) ring-shaped solder mask (solder mask ring) 52 which fully encloses the via 50 on the printed circuit board side 42 in a circumferentially continuous manner. The via 50 is open on both sides; in other words, the via 50 has an opening edge on each of the two printed circuit board sides 42, 44.

The solder mask 52 or the via 50 is integrated into the solder point 46, which means that the via 50 or the opening edge thereof and the solder mask 52 are completely enclosed or surrounded by the solder point 46 in the plane of the printed circuit board side 42. Preferably, the via 50 is also integrated into the thermal surface 48; in particular, the via 50 is connected to the thermal surface 48.

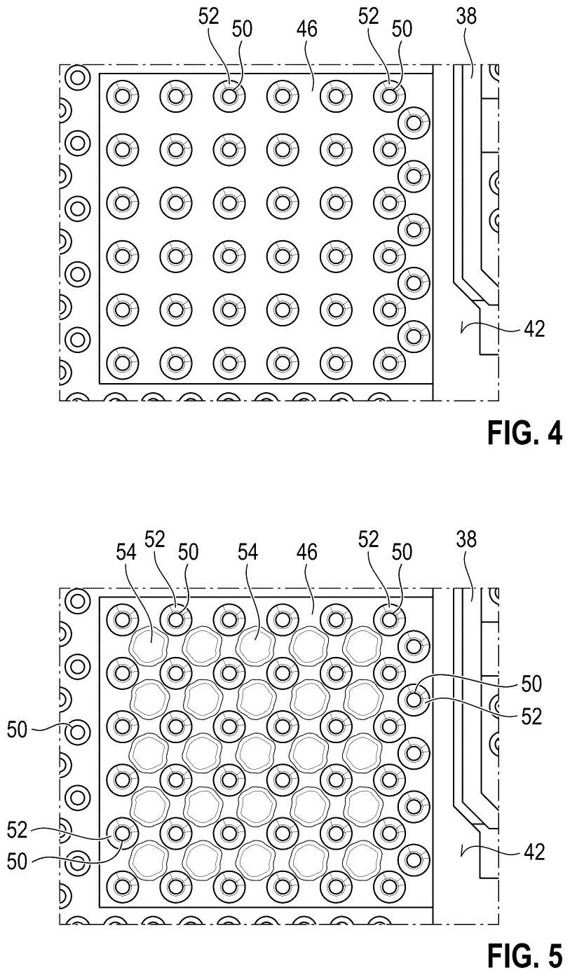

As can be seen, for example, in FIG. 3 and FIG. 4, the printed circuit board 38 has a plurality of vias 50, with those vias 50 which are integrated into the solder point 46 each being surrounded by a ring-shaped solder mask 52, so that (molten) solder or tin solder 54 applied to the solder point 46 cannot flow into the openings of the vias 50 (FIG. 5). In FIG. 5, several drops of solder 54 are applied to the solder point 46, with the solder masks 52 holding the solder 54 back from the openings of the via 50 in the manner of a dam.

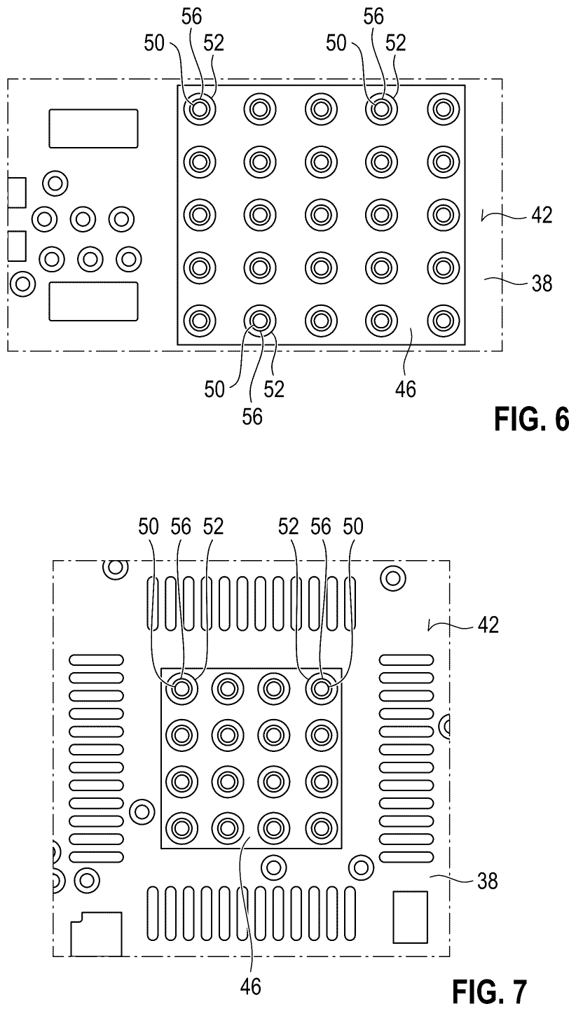

In the exemplary embodiment of FIG. 4 and FIG. 5, for example, forty-one (41) vias 50 with solder masks 52 are integrated into the solder point 46. FIG. 6 shows an exemplary embodiment with twenty-five (25) vias 50 and solder masks 52, whereas the exemplary embodiment of FIG. 7 shows sixteen (16) vias 50 with solder masks 52 in the solder point 46.

In the exemplary embodiments of FIG. 6 and FIG. 7, the vias 50 on the printed circuit board side 42 each have a ring 56 made of conductive material surrounding the opening, which ring 56 is connected to a sleeve introduced into the via 50. The solder mask 52 is respectively arranged between the ring 56 and the solder point 46.

To manufacture the printed circuit board arrangement 36, a printed circuit board 38 with a solder point 46 and a thermal surface 48 is first provided on the printed circuit board sides 42 and 44, the solder point 46 and thermal surface 48 being arranged so as to be vertically or axially aligned with one another. At least one via 50 connecting the solder point 46 and the thermal surface 48 is then introduced into the printed circuit board 38. Finally, a circumferentially continuous solder mask 52, which encloses the respective via 50, more particularly the opening thereof, is produced around the or each via 50 as a flow barrier.

Preferably, the printed circuit board side 42 is provided with a solder mask layer, i.e., a layer of solder mask material. A photoresist is applied to this solder mask layer by means of a screen printing process, exposed photolithographically, and developed, and then all areas not covered with photoresist are removed, such as the areas arranged inside and outside the solder mask rings, so that the solder masks 52 are released from the solder mask layer and remain on the printed circuit board side 42.

The solder masks 52 are applied in particular using a screen printing process, a stencil 58 being employed which has a circumferentially continuous depression 60 or cavity (cavities) in the vicinity of the solder masks 52.

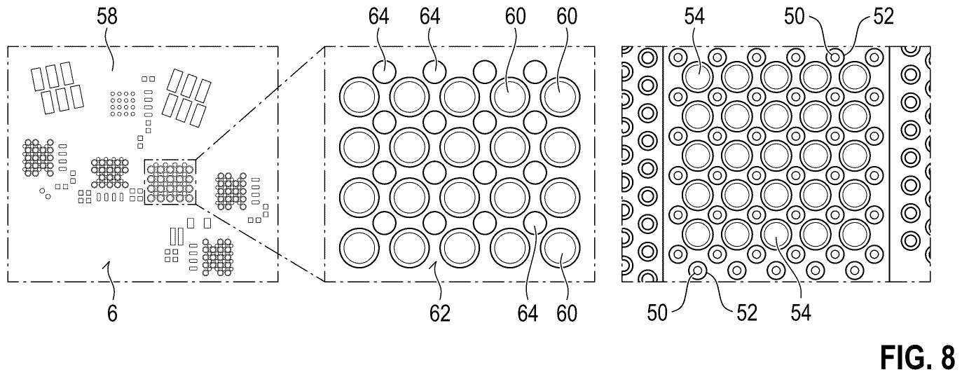

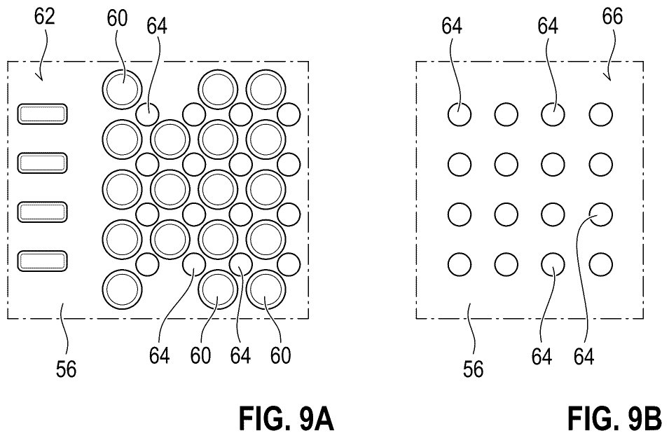

FIG. 8 shows the stencil 58 with a view of a stencil side 62 facing toward the printed circuit board 36 and having holes 64 as outlets to a squeegee-side stencil side 66 (FIG. 9). As shown in FIG. 8, the holes 64 and depressions 60 are arranged on the printed circuit board side 42 such that the depressions 60 are axially aligned over the vias 50. The holes 64 are located at the points to which the solder 54 is applied.

The stencil sides 62, 66 are shown individually in FIG. 9A and FIG. 9B.

The claimed invention is not limited to the exemplary embodiments described above. Rather, other variants of the invention can also be derived therefrom by a person skilled in the art within the scope of the disclosed claims, without departing from the subject matter of the claimed invention. In particular, all the individual features described in connection with the various exemplary embodiments can also be combined in other ways within the scope of the disclosed claims, without departing from the subject matter of the claimed invention.

In the exemplary embodiments described above, the vias 50 each have a circular cross section and the solder masks 52 have a circular ring shape. However, other cross-sectional shapes and ring shapes, such as polygonal designs, are also conceivable. What is essential here is that the solder mask 52 encloses the opening of the respective via 50 in a circumferentially continuous manner and thus blocks or prevents the inflow or flow of solder 54 into the via 50.

It is also possible that, in the case of multiple integrated vias 50, the individual vias 50 and solder masks 52 (or depressions in the stencil) have different geometries from one another.

The following is a summary list of reference numerals and the corresponding structure used in the above description of the invention:
2 radiator fan
4 electric motor
6 rotor
8 stator
10 axle pin
12 bearing
14 fan wheel
16 hub pot
18 blade
20 motor mount
22 flange
24 electronics unit
26 electronics compartment
28 electronics
30 cover
32 cable
34 rotating-field winding
36 printed circuit board arrangement
38 printed circuit board
40 component
42 printed circuit board side
44 printed circuit board side
46 solder point
48 thermal surface
50 via
52 solder mask
54 solder
56 ring
58 stencil
60 depression
62 stencil side
64 hole
66 stencil side
A axial direction
R radial direction
D axis of rotation

1. A printed circuit board configuration for an electronics unit, the printed circuit board configuration comprising:
a printed circuit board with a first printed circuit board side on which at least one solder point for contacting an electronic component is disposed, and with an oppositely situated printed circuit board side on which a thermal surface is disposed, wherein said thermal surface is disposed so as to be vertically aligned with said at least one solder point, wherein said printed circuit board having at least one via formed therein and connecting said at least one solder point to said thermal surface, and wherein said at least one via is enclosed by a circumferentially continuous solder mask acting as a flow barrier.

2. The printed circuit board configuration according to claim 1, wherein said at least one via is open on both sides.

3. The printed circuit board configuration according to claim 1, wherein said at least one via is disposed completely within said at least one solder point and said thermal surface.

4. The printed circuit board configuration according to claim 1, wherein said circumferentially continuous solder mask is disposed on said first printed circuit board side.

5. The printed circuit board configuration according to claim 1, wherein said at least one via is connected to said thermal surface.

6. A method for manufacturing a printed circuit board configuration, which comprises the steps of:
providing a printed circuit board having a first printed circuit board side on which at least one solder point for contacting an electronic component is disposed and with an oppositely situated printed circuit board side on which a thermal surface is disposed so as to be aligned with the at least one solder point;
introducing at least one via into the printed circuit board, the at least one via connecting the at least one solder point and the thermal surface; and
producing a circumferentially continuous solder mask enclosing around the at least one via, the at least one via functioning as a flow barrier.

7. The method according to claim 6, which further comprises producing the circumferentially continuous solder mask by means of a screen printing process.

8. The method according to claim 7, which further comprises using a stencil in the screen printing process which has a circumferentially continuous depression in a vicinity of the circumferentially continuous solder mask.

9. An electronics unit for an electric motor, the electronics unit comprising:
said printed circuit board configuration according to claim 1; and
an electronic component electrically solder-connected to said at least one solder point.

10. The electronics unit according to claim 9, further comprising a heat sink, said thermal surface is connected in a thermally conductive manner to said heat sink.
